(19) United States
(12) Patent Application Publication
(10) Pub. No.: US 2006/0087017 A1
(43) Pub. Date: Apr. 27, 2006

(54) Image sensor package

(75) Inventors: Yeong-Ching Chao, Tainan (TW); An-Hong Liu, Tainan (TW); Yao-Jung Lee, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS TECHNOLOGIES (Bermuda) LTD.; ChipMOS TECHNOLOGIES INC.

(21) Appl. No.: 11/254,658

(22) Filed: Oct. 21, 2005

(30) Foreign Application Priority Data
Oct. 21, 2004 (TW) 093216781

(51) Int. Cl. H01L 23/02

(52) U.S. Cl. 257/680

(57) ABSTRACT

An image sensor package includes a chip carrier, an image sensor chip, a transparent cover, and an O-ring. The chip carrier has a plurality of inner leads. The image sensor chip has an active surface including a sensing area and a plurality of bonding pads thereon. The bonding pads are electrically connected to the inner leads by bumps or bonding wires. The transparent cover is disposed on the chip carrier. Moreover, the O-ring includes a photocurable adhesive to hermetically sealing the image sensor chip under low temperatures.

### FIELD OF THE INVENTION

The present invention relates to an image sensor package, and more particularly, to an image sensor package under low-temperature hermetic sealing.

BACKGROUND OF THE INVENTION

Image sensor devices are one kind of semiconductor devices which can convert the light signals into digital signals for images storage or display. More and more portable electronic devices are equipped with image sensor modules, such as digital still camera (DSC), digital video camera (DV), cellular phone, and personal digital assistant (PDA).

Shown in FIG. 1 is a conventional image sensor package, as revealed in R.O.C. Taiwan patent publication No. 484237 entitled “An optical device with a tape packaging type”. The image sensor package with TCP (tape carrier package) type includes an image sensor chip 110, a flexible wiring tape 120, a molding base 130, and a transparent cover 140. The flexible wiring tape 120 has an upper surface 121, a bottom surface 122, and a window opening 123. The molding base 130 has a cavity 131 for holding the image sensor chip 110. Moreover, the cavity 131 covers the bottom surface 122 of the flexible wiring tape 120. The molding base 130 has a protrusion ring 132 extended to the upper surface 121 of the flexible wiring tape 120. The transparent cover 140 is attached to the upper surface of the protrusion ring 132 by a thermosetting adhesive 150 so that the image sensor chip 110 can be hermetically sealed in the cavity 131 to prevent moisture or dust to damage the image sensor chip 110. However, the thermosetting adhesive 150 has to be cured using a curing furnace, i.e., the image sensor chip 110 will also pass through the curing heat cycle. Internal sensor components in the image sensor chip 110 are easily damaged, internal stress will be generated in the image sensor package, and eventually leads to poor reliability.

### SUMMARY OF THE INVENTION

The main purpose of the present invention is to provide an image sensor package having an O-ring between a transparent cover glass and a chip carrier. The O-ring includes a photocurable adhesive for hermetically sealing an image sensor chip inside under low temperatures. Photoinitiator of the photocurable adhesive can be cured by the radiation of laser beams, UV light or blue light to replace conventional thermal curing adhesives. No thermal stresses will be induced into the image sensor package, therefore, the image sensor chip will not be damaged by thermal shock. Therefore, the reliability of the image sensor package can be enhanced.

According to the present invention, an image sensor package comprises a chip carrier, an image sensor chip, a transparent cover, and an O-ring. The chip carrier may be a flexible wiring board or a rigid substrate with a stiffener. The chip carrier includes a metal trace layer which has a plurality of inner leads. The image sensor chip has an active surface and a back surface wherein a sensing area and a plurality of bonding pads are formed on the active surface. A plurality of bumps are formed on the bonding pads. The bumps are bonded to the inner leads for electrical connection between the bonding pads and the inner leads. The transparent cover is disposed on the chip carrier. The O-ring is formed between the transparent cover and the chip carrier to hermetically seal the image sensor chip inside. Moreover, the O-ring includes a photocurable adhesive which can be cured by the radiation of light.

### DESCRIPTION OF THE DRAWINGS

FIG. 1 is a cross-sectional view of a conventional image sensor package disclosed in R.O.C. Taiwan patent publication No. 484237.

FIG. 2 is a cross-sectional view of an image sensor package according to the first embodiment of the present invention.

FIG. 3 is a cross-sectional view of an image sensor package according to the second embodiment of the present invention.

FIG. 4 is a cross-sectional view of an image sensor package according to the third embodiment of the present invention.

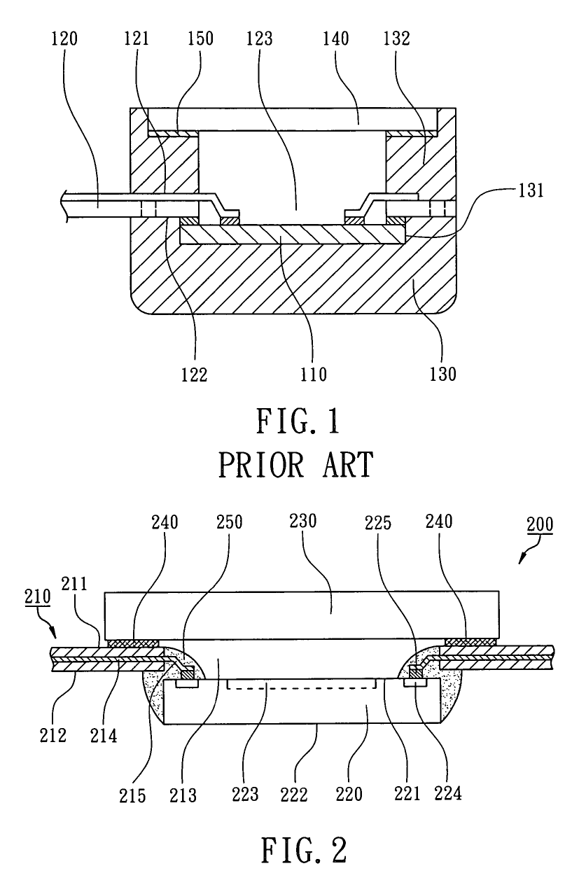

### DETAIL DESCRIPTION OF THE INVENTION

Please refer to the attached drawings, the present invention will be described by means of embodiment(s) below. FIG. 2 shows an image sensor package 200 according to the first embodiment of the present invention, which comprises a chip carrier 210, an image sensor chip 220, a transparent cover 230 and an O-ring 240. In this embodiment, the chip carrier 210 is a flexible wiring substrate, for example, its substrate core is polyimide (PI). The chip carrier 210 has an upper surface 211, a bottom surface 212 and an opening 213 penetrating the upper surface 211 and the bottom surface 212. The chip carrier 210 also has a metal trace layer 214 including a plurality of inner leads 215, wherein the inner leads 215 may be TAB (Tape Automated Bonding) leads extended to the opening 213.

The image sensor chip 220 may be a charge coupled device (CCD), a CMOS image sensor chip, or a photodiode. The image sensor chip 220 has an active surface 221 and a back surface 222 where a sensing area 223 and a plurality of bonding pads 224 are formed on the active surface 221. According to this embodiment, the image sensor chip 220 is a bumped chip where a plurality of bumps 225 are formed on the bonding pads 224. When performing flip-chip bonding by solder reflowing, ACF connection, NCP connection, eutectic bonding or thermo-ultrasonic bonding, the bumps 225 are bonded to the inner leads 215 for electrical connection between the bonding pads 224 and the inner leads 215. The bumps 225 and the inner leads 215 can be encapsulated by an encapsulant 250 which can be selected from the group consisting of anisotropic conductive film (ACF), non-conductive paste (NCP) and underfilling material. The transparent cover 230, such as an optical glass, is disposed on the chip carrier 210 aligned with the opening 213. A hermetic space is formed between the transparent cover 230, the chip carrier 210 and the image sensor chip 220 by the O-ring 240 where the sensing area 223 is located on the image sensor chip 220. The O-ring 240 includes a photocurable adhesive, such as epoxy resin mixed with photoinitiator and so on. After radiation by a laser beam, UV light, or blue light, the photoinitiator will initiate polymerization and is cured to form the O-ring 240. During the radiation, the intensity of laser beams or UV light should not be less than 50 mW/cm² and the blue light not less than 100 mW/cm².

Since the laser beams, UV light, and blue light can penetrate the transparent cover 230 and radiate on the O-ring 240 to initiate polymerization of photoinitiator. Therefore, the transparent cover 230 can adhere to the chip carrier 210 without thermal curing to avoid thermal stresses and thermal shock to enhance the reliability of the image sensor package 200.

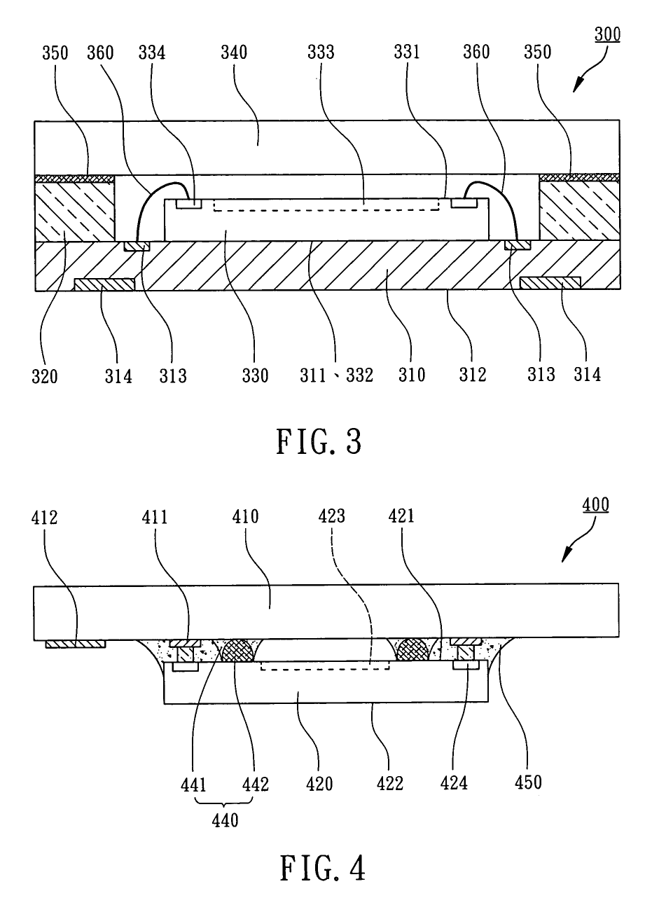

As shown in FIG. 3, an image sensor package 300 according to the second embodiment of the present invention, comprises a chip carrier consisting of a rigid substrate 310 and a stiffener 320, an image sensor chip 330, a transparent cover 340, and an O-ring 350. Therein, the stiffener 320 is secured to the rigid substrate 310 to form a chip carrier with a cavity. The rigid substrate 310 can be a BT, FR-4, or FR5 PCB, or a ceramic substrate. The rigid substrate 310 has an upper surface 311 and a bottom surface 312 where a plurality of inner leads 313 are formed on the upper surface 311, and a plurality of external pads 314 are formed on the bottom surface 312. The external pads 314 are electrically connected to the inner leads 313. The image sensor chip 330 has an active surface 331 and a back surface 332 where a sensing area 333 and a plurality of bonding pads 334 are formed on the active surface 331. The back surface 332 is attached to the upper surface 311 so that the image sensor chip 330 is located in the cavity of the chip carrier. According to the second embodiment of the present invention, a plurality of bonding wires 360 electrically connect the bonding pads 334 to the inner leads 313. The transparent cover 340 is disposed on the stiffener 320. The O-ring 350 is formed between the transparent cover 340 and the stiffener 320 to hermetically seal the image sensor chip 330. The O-ring 350 includes a photocurable adhesive. Through the radiation of a laser beam or UV light with the intensity not less than 50 mW/cm² or blue light not less than 100 mW/cm², a polymerization can be initiated to cure the photocurable adhesive as the O-ring 350 to firmly adhere the transparent cover 340 to the stiffener 320.

FIG. 4 is a cross-section view of an image sensor package 400 according to the third embodiment of the present invention. The image sensor package 400 comprises a glass substrate 410, an image sensor chip 420, a plurality of bumps 430, and an O-ring 440. Therein, the glass substrate 410 has a plurality of inner leads 411 and a plurality of outer lead 412 on the trace layer. The image sensor chip 420 has an active surface 421 and a back surface 422 where a sensing area 423 and a plurality of bonding pads 424 are formed on the active surface 421. The image sensor chip 420 is flip-chip bonded to the glass substrate 410 by the bumps 430. As a result, the bumps 430 electrically connect the bonding pads 424 and the inner leads 411. In this embodiment, the back surface 422 is exposed. The O-ring 440 is formed between the glass substrate 410 and the image sensor chip 420, wherein the O-ring 440 includes a photocurable adhesive 441 to hermetically sealing the sensing area 423 of the image sensor chip 420. In this embodiment, the O-ring 440 further includes an elastic dam 442 to provide an elastic flip-chip bonding gap for NCP 450. The material of the elastic dam 442 may be rubber or silicone. Preferably, the photocurable adhesive 441 may be coated on the glass substrate by dispensing or printing, and the elastic dam 442 is formed on the image sensor chip 420 before flip-chip bonding. Accordingly, a laser beam or UV light easily passes through the glass substrate 410 such that a polymerization can be initiated to cure the photocurable adhesive 441 under low temperatures or room temperatures.

The above description of embodiments of this invention is intended to be illustrative and not limiting. Other embodiments of this invention will be obvious to those skilled in the art in view of the above disclosure.

What is claimed is:

1. An image sensor package comprising:
a chip carrier having a plurality of inner leads;
an image sensor chip having an active surface and a back surface, wherein a sensing area and a plurality of bonding pads are formed on the active surface, the bonding pads are electrically connected to the inner leads;
a transparent cover disposed on the chip carrier; and
an O-ring formed between the transparent cover and the chip carrier to hermetically sealing the image sensor chip, wherein the O-ring includes a photocurable adhesive.

2. The image sensor package of claim 1, wherein the photocurable adhesive is cured by the radiation of a laser beam, UV light, or blue light.

3. The image sensor package of claim 2, wherein the UV light intensity is not less than 50 mW/cm².

4. The image sensor package of claim 1, wherein the chip carrier is a flexible wiring substrate having an upper surface, a bottom surface, and an opening penetrating the upper surface and the bottom surface, the opening is aligned with the sensing area.

5. The image sensor package of claim 4, wherein the inner leads are TAB leads extending to the opening.

6. The image sensor package of claim 1, further comprising a plurality of bumps formed on the bonding pads.

7. The image sensor package of claim 6, further comprising an encapsulant encapsulating the bumps.

8. The image sensor package of claim 7, wherein the encapsulant is selected from the group consisting of anisotropic conductive film (ACF), non-conductive paste (NCP), and underfilling material.

9. The image sensor package of claim 1, wherein the chip carrier includes a rigid substrate and a stiffener, wherein the O-ring connects the stiffener and the transparent cover.

10. The image sensor package of claim 1, wherein the O-ring further includes an elastic dam, the photocurable adhesive is coated on the transparent cover, the elastic dam is formed on the chip carrier.

11. An image sensor package comprising:
a glass substrate having a plurality of inner leads;
an image sensor chip having an active surface and a back surface, wherein a sensing area and a plurality of bonding pads are formed on the active surface;
a plurality of bumps electrically connecting the bonding pads and the inner leads; and
an O-ring formed between the glass substrate and the image sensor chip to hermetically sealing the sensing area, wherein the O-ring includes a photocurable adhesive.

12. The image sensor package of claim 11, further comprising an encapsulant encapsulating the bumps.

13. The image sensor package of claim 12, wherein the encapsulant is non-conductive paste (NCP).

14. The image sensor package of claim 13, wherein the O-ring further includes an elastic dam.

15. The image sensor package of claim 14, wherein the elastic dam adheres to the image sensor chip.

16. The image sensor package of claim 11, wherein the O-ring further includes an elastic dam.

17. The image sensor package of claim 16, wherein the photocurable adhesive is coated on the glass substrate, the elastic dam is formed on the image sensor chip.
